(19) United States
(12) Patent Application Publication
(10) Pub. No.: US 2014/0092027 A1
(43) Pub. Date: Apr. 3, 2014

(54) TOUCH PANEL AND METHOD FOR PRODUCING SAME

(71) Applicant: avct Optical Electronic Co., Ltd, (US)

(72) Inventors: TING-CHING KUO, CHUNG LI CITY (TW); JYR-DWO LEE, CHUNG LI CITY (TW); SHIH-LIANG CHOU, CHUNG LI CITY (TW); CHIEN-MIN WENG, CHUNG LI CITY (TW); HSUEH-CHIH CHIANG, CHUNG LI CITY (TW)

(73) Assignee: AVCT OPTICAL ELECTRONIC CO., LTD, CHUNG LI CITY (TW)

(21) Appl. No.: 13/630,805

(22) Filed: Sep. 28, 2012

(51) Int. Cl. H05K 3/02; G06F 3/041

(52) U.S. Cl. 345/173; 427/97.4; 216/13; 427/523

(57) ABSTRACT

The invention relates to a touch panel. The touch panel includes a plastic film substrate, whose two surfaces are provided in sequence with at least two undercoat layers and a patterned transparent conductive layer and further provided with a patterned metal circuit layer, respectively. The invention also relates to a simplified method for producing a touch panel, in which the conventional lamination process is eliminated, and the touch panel produced thereby has a reduced overall thickness and is free of the conventional image deterioration drawback. Moreover, the method generally pertains to a sheet-by-sheet process and is superior over the conventional roll-to-roll processes in which the thin layers tend to exfoliate due to the occurrence of uneven tension.

### BACKGROUND OF THE INVENTION

1. Field of the Invention

The present invention relates to a touch panel and its production and, more particularly, to a simplified method for producing a touch panel, in which the conventional lamination process is omitted, and the touch panel produced thereby, in which the conventional drawback of image deterioration caused by the patterning of the transparent conductive layers is largely eliminated.

2. Description of the Prior Art

With the advancement of touch-screen technology in recent years, touch panels have been widely used in a broad variety of electronic devices, including mobile phones, personal digital assistants (PDAs), input interfaces of game consoles, and computer touch-screens. In the actual practice, a touch panel is typically combined with a liquid crystal display (LCD) device to constitute a touch screen adaptable to various electronic devices, through which a user can conveniently input data and instructions without relying upon a traditional input device, such as a keyboard or a computer mouse.

In general, the transparent conductive glass used in a touch panel is primarily composed of a transparent, non-conductive glass substrate, on which a transparent material with high electrical conductivity, typically a transparent metal oxide such as indium tin oxide (ITO), is coated to form a transparent conductive layer. The transparent conductive layer is etched into a predetermined electrode pattern in the form of, for example, a unidirectional electrode array.

Therefore, the transparent conductive layer contains a patterned region (which is formed with electrodes) and a non-patterned region (the etched-away portion). The non-patterned region is not provided with ITO, allowing light to directly penetrate therethrough to reach the glass substrate. Since the patterned and non-patterned regions have substantially different refractive indexes, the user would notice the presence of the etch lines at the junctions between the patterned and non-patterned regions. As a result, images displayed on the screen are deteriorated due to the occurrence of discontinuity, haziness, granulation and low resolution in the images.

In the case of fabrication of a bidirectional electrode array, it is traditionally made by laminating two transparent conductive films patterned with electrode patterns. During the lamination process, however, it is difficult to achieve stable bridging and precise registration between two transparent conductive films, resulting in decreased reliability and quality control of the touch panels thus fabricated.

### SUMMARY OF THE INVENTION

An object of the invention is to provide a simplified method for producing a touch panel, in which the conventional lamination process is eliminated.

In order to achieve the object described above, the touch panel according to the invention comprises a plastic film substrate having a first surface and a second surface opposite to the first surface. The first surface is provided in sequence with a first undercoat layer, a second undercoat layer and a first patterned transparent conductive layer, and the first surface is further printed with a first patterned metal circuit layer along the periphery of the first patterned transparent conductive layer. The second surface is provided in sequence with a third undercoat layer, a fourth undercoat layer and a second patterned transparent conductive layer, and the second surface is further printed with a second patterned metal circuit layer along the periphery of the second patterned transparent conductive layer.

In a preferred embodiment, the plastic film substrate has a thickness ranging from 2 μm to 300 μm, more preferably from 2 μm to 200 μm.

Another object of the invention is to provide a method for producing a touch panel, comprising the steps of:
Step A: providing a plastic film material;
Step B: cutting the plastic film material to obtain a sheet-like plastic film substrate having a first surface and a second surface opposite to the first surface and placing the plastic film substrate on a support frame for subsequent processing;
Step C: forming in sequence a first undercoat layer, a second undercoat layer and a first transparent conductive layer on the first surface of the plastic film substrate, and forming in sequence a third undercoat layer, a fourth undercoat layer and a second transparent conductive layer on the second surface of the plastic film substrate;
Step D: patterning the first and second transparent conductive layers into a first patterned transparent conductive layer and a second patterned transparent conductive layer, respectively;
Step E: forming a first patterned metal circuit layer and a second patterned metal circuit layer on the first and second surfaces of the plastic film substrate along the peripheries of the first and second patterned transparent conductive layers using a printing process, respectively; and
Step F: baking the resultant device to cure the first and second patterned metal circuit layers.

In a preferred embodiment, the method described above may further comprise a Step G intervening between the Step D and the Step E, wherein the Step G comprises annealing the first and second patterned transparent conductive layers, so as to have the layers crystallized.

In a preferred embodiment, the annealing Step G is performed at a temperature of 100˜200° C. for 30˜90 minutes.

In a preferred embodiment, the Step D comprises the sub-steps of:
Step D-1: applying a temporary protective film the second transparent conductive layer;
Step D-2: supporting the plastic film substrate on a support member, with the second transparent conductive layer facing downwardly;
Step D-3: forming a first patterned etching-resistant layer over the first transparent conductive layer;
Step D-4: reversing the plastic film substrate with respective to the support member, with the first transparent conductive layer facing downwardly;
Step D-5: removing the temporary protective film applied over the second transparent conductive layer;
Step D-6: forming a second patterned etching-resistant layer over the second transparent conductive layer;
Step D-7: etching the first and second transparent conductive layers to remove the regions thereof unprotected by the first and second patterned etching-resistant layers; and
Step D-8: removing the first and second patterned etching-resistant layers.

In an alternative preferred embodiment, the Step D comprises the sub-steps of:
Step D-10: applying a temporary protective film over the second transparent conductive layer;
Step D-20: supporting the plastic film substrate on a support member, with the second transparent conductive layer facing downwardly;
Step D-30: forming a first patterned etching-resistant layer over the first transparent conductive layer;
Step D-40: etching the first transparent conductive layer to remove the regions thereof unprotected by the first patterned etching-resistant layer, thereby forming a first patterned transparent conductive layer;
Step D-50: removing the first patterned etching-resistant layer and applying a temporary protective film over the first patterned transparent conductive layer;
Step D-60: reversing the plastic film substrate with respective to the support member, with the first patterned transparent conductive layer facing downwardly;
Step D-70: removing the temporary protective film applied over the second transparent conductive layer;
Step D-80: forming a second patterned etching-resistant layer over the second transparent conductive layer;
Step D-90: etching the second transparent conductive layer to remove the regions thereof unprotected by the second patterned etching-resistant layer, thereby forming a second patterned transparent conductive layer; and
Step D-100: removing the second patterned etching-resistant layer.

In a preferred embodiment, the undercoat layers and transparent conductive layers are formed in the Step C by using a dry process selected from the group consisting of vacuum evaporation, sputtering and ion plating, or by using a wet process.

In a preferred embodiment, the first and second patterned metal circuit layers are formed in Step E by screen printing of conductive silver paste onto the plastic film substrate.

In a preferred embodiment, the baking Step F is performed at a temperature of 100˜200° C.

According to the present invention, the following advantageous effects will be obtainable.

1. The invention involves direct formation of transparent conductive patterns on both sides of the plastic film substrate, whereby the lamination and precise registration operations required for the conventional methods are eliminated, and the touch panel thus produced has a reduced overall thickness compared to the conventional touch panels.

2. The invention successfully overcomes the drawback of image deterioration caused by the patterning of the transparent conductive layers and reduces the optical difference between the patterned regions and the non-patterned regions by adjusting the refractive indexes and thicknesses of the various thin layers that constitute the transparent conductive film.

3. The invention generally pertains to a sheet-by-sheet process and is superior over the conventional roll-to-roll processes in which the thin layers applied on the plastic film substrate (such as undercoat layers and patterned transparent conductive layers) tend to easily exfoliate due to the occurrence of uneven tension.

### BRIEF DESCRIPTION OF THE DRAWINGS

The above and other objects, features and effects of the invention will become apparent with reference to the following description of the preferred embodiments taken in conjunction with the accompanying drawing, in which:

FIG. 1 is a schematic diagram illustrating the structure of the touch panel according to the invention;

FIG. 2 is a flowchart of the method for producing a touch panel according to the invention; and

FIGS. 3 (A)˜(F) are schematic diagrams illustrating the stepwise operations for producing a touch panel according to the invention.

### DETAILED DESCRIPTION OF THE PREFERRED EMBODIMENTS

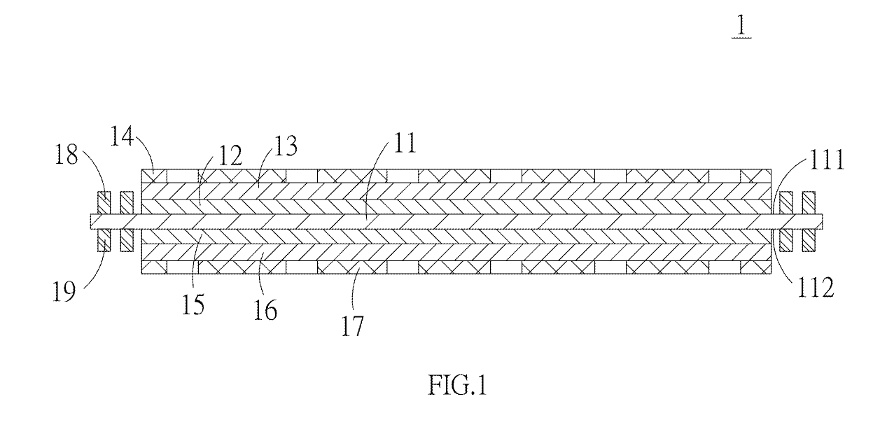

FIG. 1 is a schematic diagram illustrating the structure of the transparent conductive film according to the invention. As illustrated, the transparent conductive film 1 disclosed herein comprises a plastic film substrate 11 having a first surface 111 and a second surface 112 opposite to the first surface 111. The first surface 111 is provided in sequence with a first undercoat layer 12, a second undercoat layer 13 and a first patterned transparent conductive layer 14. The second surface 112 is provided in sequence with a third undercoat layer 15, a fourth undercoat layer 16 and a second patterned transparent conductive layer 17. The first surface 111 is further printed with a first patterned metal circuit layer 18 along the periphery of the first patterned transparent conductive layer 14, whereas the second surface 112 is further printed with a first patterned metal circuit layer 19 along the periphery of the second patterned transparent conductive layer 15.

The plastic film substrate used in the invention can be any type of plastic film that is transparent to light. The material from which the plastic film substrate is made is not critical under the spirit of the invention, which includes but is not limited to polyester resins, acetate resins, polyethersulfone resins, polycarbonate resins, polyamide resins, polyimide resins, polyolefin resins, methacrylate resins, polyvinylchloride resins, polyvinylidine chloride resins, polystyrene resins, polyvinyl alcohol resins, polyarylate resins, and polyphenylene sulfide resins.

Preferred are polyester resins, polycarbonate resins and polyolefin resins. Advantageously, the plastic film substrate has a thickness ranging from 2 μm to 300 μm, preferably from 2 μm to 200 μm.

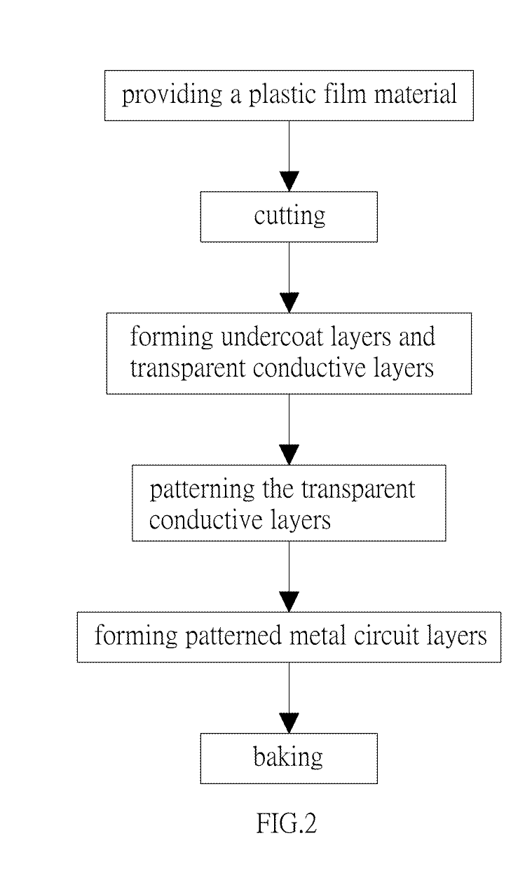

FIG. 2 shows a method for producing the touch panel disclosed herein, which comprises the steps of:

Step A: providing a plastic film material.

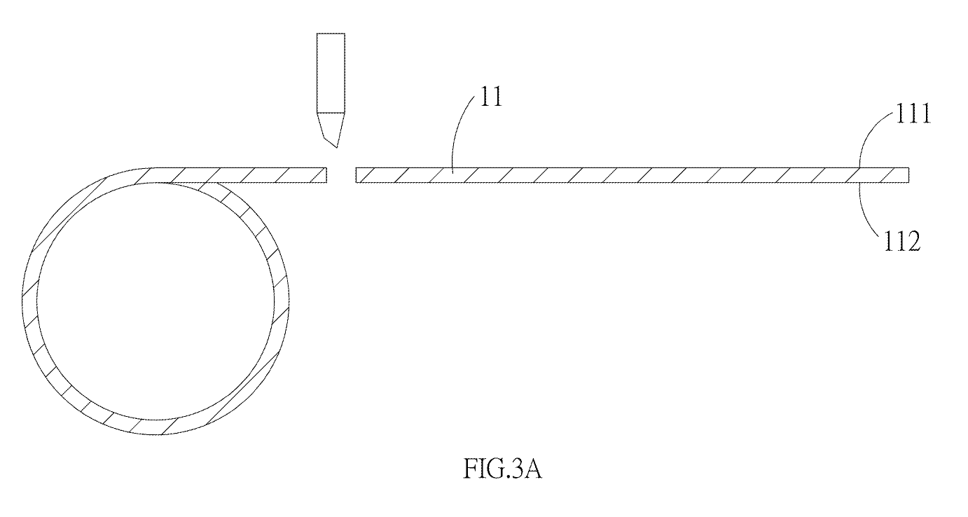

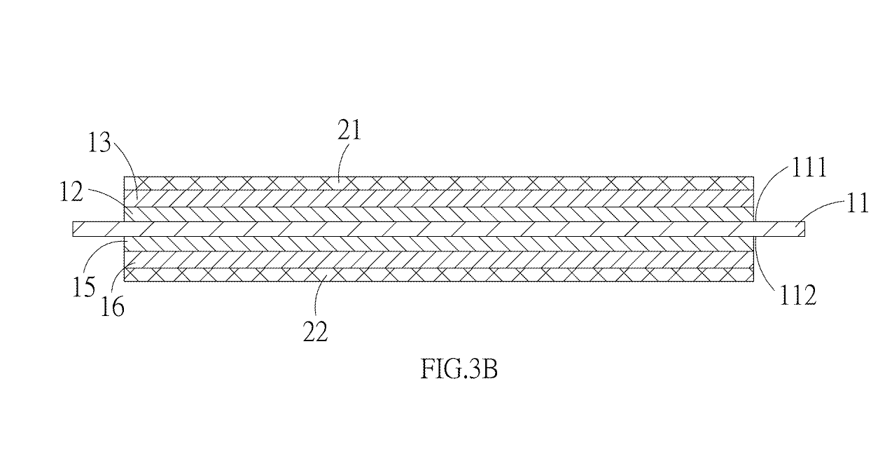

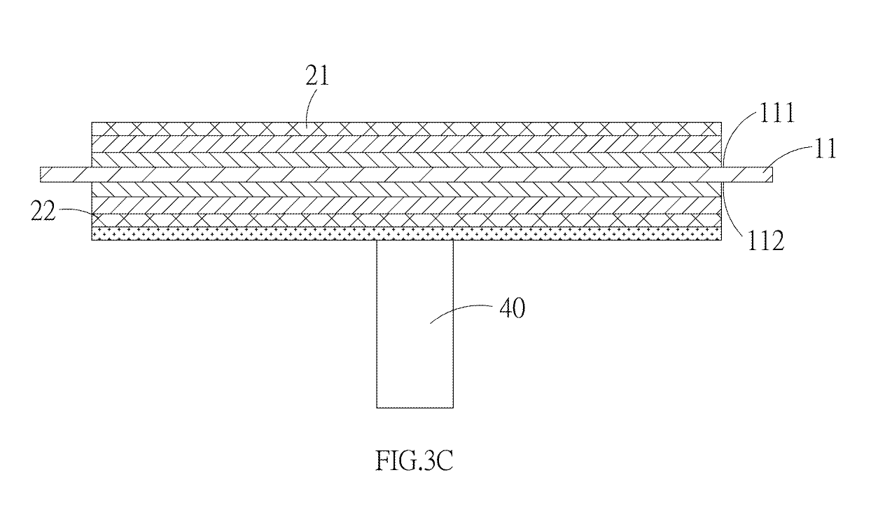

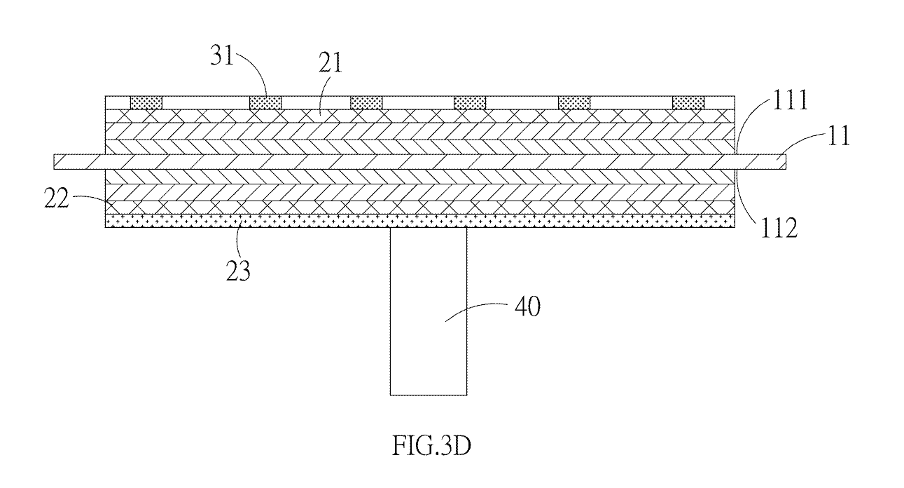

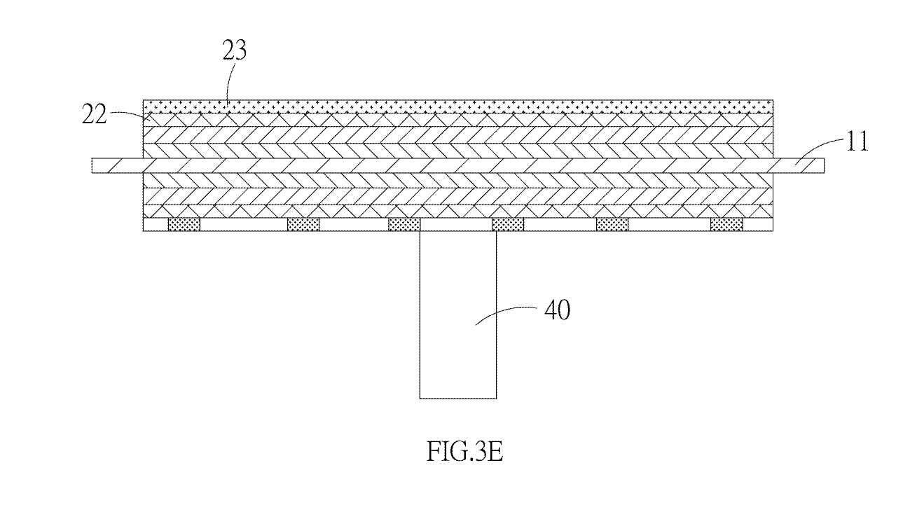

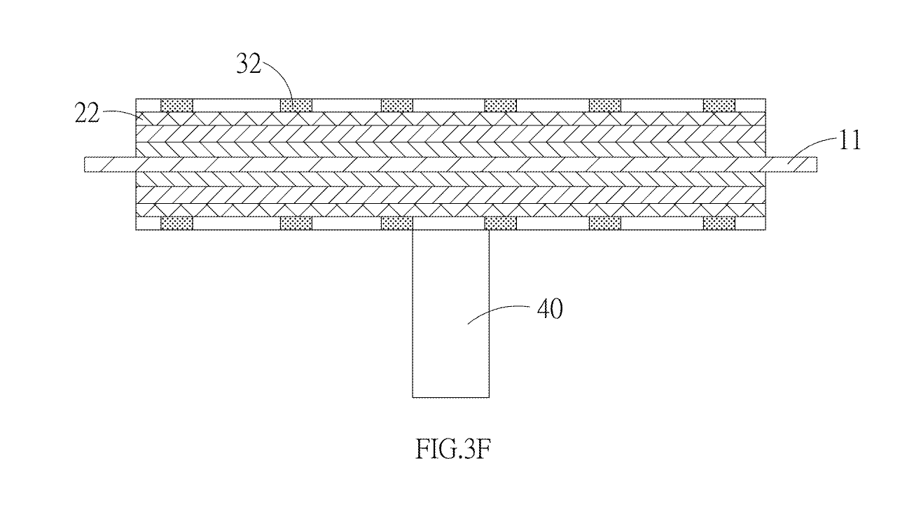

Step B: cutting the plastic film material to obtain a sheet-like plastic film substrate 11 as shown in FIG. 3(A) and placing the plastic film substrate 11 on a support frame for subsequent processing, wherein the plastic film substrate 11 may be subjected to a pre-aging treatment, for example, at 70° C. for about 30 minutes.

Step C: forming undercoat layers and transparent conductive layers on the plastic film substrate 11 through a dry process, such as vacuum evaporation, sputtering and ion plating, or through a wet process, such as coating, whereby the plastic film substrate 11 comprises a first surface 111, on which a first undercoat layer 12, a second undercoat layer 13 and a first transparent conductive layer 21 are formed in sequence as shown in FIG. 3(B), and a second surface 112 opposite to the first surface 111, on which a third undercoat layer 15, a fourth undercoat layer 16 and a second transparent conductive layer 22 are formed in sequence. The first and third undercoat layers may be independently made of a niobium oxide (NbOₓ), a titanium oxide (TiOₓ) or a tantalum oxide (TaOₓ) and the second and fourth undercoat layers may be made of silicon dioxide (SiO₂). The material from which the first and second transparent conductive layers 21, 22 are made is not critical under the spirit of the invention and preferably comprises an oxide of at least one metal selected from the group consisting of indium, tin, zinc, potassium, antimony, titanium, silicon, zirconium, magnesium, aluminum, gold, silver, copper, palladium and tungsten. Optionally, the material may further comprise one of the metals described above in its element form. Preferred are indium oxide doped with tin oxide, and tin oxide doped with antimony. Preferably, the first and second transparent conductive layers 21, 22 have a thickness of 20˜35 nm.

Step D: patterning the first and second transparent conductive layers 21, 22 into a first patterned transparent conductive layer and a second patterned transparent conductive layer, respectively. The Step D comprises the following sub-Steps. In Step D-1, a temporary protective film 23 is applied over the second transparent conductive layer 22, as shown in FIG. 3(C). In Step D-2, the plastic film substrate 11 is supported on a support member 40, with the second transparent conductive layer 22 facing downwardly and being protected by the temporary protective film 23. In Step D-3, a first patterned etching-resistant layer 31 is formed over the first transparent conductive layer 21 as shown in FIG. 3(D) through, for example, a printing process. In Step D-4, the plastic film substrate 11 is reversed with respective to the support member 40 with the first transparent conductive layer 21 facing downwardly, as shown in FIG. 3(E). In Step D-5, the temporary protective film 23 applied over the second transparent conductive layer 22 is removed, as shown in FIG. 3(F). In Step D-6, a second patterned etching-resistant layer 32 is formed over the second transparent conductive layer 22. In Step D-7, the first and second transparent conductive layers 21, 22 are etched (using, for example, photolithography) to remove the regions thereof unprotected by the first and second patterned etching-resistant layers 31, 32. In Step D-8, the first and second patterned etching-resistant layers 31, 32 are removed to reveal the first and second patterned transparent conductive layers 14, 17 shown in FIG. 1. The patterning of the first and second transparent conductive layers 21, 22 results in patterned regions with any desired shape, such as a bar-like or block-like shape, and non-patterned regions.

Step E: forming a first patterned metal circuit layer 18 and a second patterned metal circuit layer 19 on the plastic film substrate 11 along the peripheries of the first and second patterned transparent conductive layers 14, 17 using a printing process, as shown in FIG. 1. The first and second patterned metal circuit layers 18, 19 comprises a plurality of conductive wires, which may optionally be fabricated by screen printing of conductive silver paste onto the plastic film substrate 11 along the peripheries of the first and second patterned transparent conductive layers 14, 17. The first and second patterned metal circuit layers 18, 19 are electrically connected to the first and second patterned transparent conductive layers 14, 17, respectively, so that the touch signals sensed by the first and second patterned transparent conductive layers 14, 17 are transmitted along with electrical magnetic noise to a downstream microprocessor for further signal processing.

Step F: baking the resultant device at a temperature of 100˜200° C. to cure the first and second patterned metal circuit layers 18, 19.

The method described above may further comprise a Step G intervening between the Step D and the Step E, which comprises annealing the first and second patterned transparent conductive layers at a temperature of 100˜200° C. for about 30˜90 minutes, so as to have the layers crystallized.

Alternatively, the Step D described above comprises the following sub-Steps. In Step D-10, a temporary protective film is applied over the second transparent conductive layer. In Step D-20, the plastic film substrate is supported on a support member, with the second transparent conductive layer facing downwardly. In Step D-30, a first patterned etching-resistant layer is formed over the first transparent conductive layer. In Step D-40, the first transparent conductive layer is etched to remove the regions thereof unprotected by the first patterned etching-resistant layer, thereby forming a first patterned transparent conductive layer. In Step D-50, the first patterned etching-resistant layer is removed and a temporary protective film is applied over the first patterned transparent conductive layer. In Step D-60, the plastic film substrate is reversed with respective to the support member with the first patterned transparent conductive layer facing downwardly. In Step D-70, the temporary protective film applied over the second transparent conductive layer is removed. In Step D-80, a second patterned etching-resistant layer is formed over the second transparent conductive layer. In Step D-90, the second transparent conductive layer is etched to remove the regions thereof unprotected by the second patterned etching-resistant layer, thereby forming a second patterned transparent conductive layer. In Step D-100, the second patterned etching-resistant layer is removed to reveal both of the first and second patterned transparent conductive layers.

It is worthwhile to note that the method disclosed herein involves direct formation of transparent conductive patterns on both sides of the plastic film substrate, whereby the lamination and precise registration operations required for the conventional methods are eliminated. As such, the method disclosed herein is not only simplified as compared to the conventional methods but adapted to produce a touch panel with reduced overall thickness as compared to the conventional devices. Moreover, the method disclosed herein generally pertains to a sheet-by-sheet process and is superior over the conventional roll-to-roll processes in which the thin layers applied on the plastic film substrate (such as undercoat layers and patterned transparent conductive layers) tend to easily exfoliate due to the occurrence of uneven tension.

In addition, the first and second undercoat layers 12, 13 have refractive indexes of N1 and N2, respectively, and have thicknesses of T1 and T2, respectively, and the first patterned transparent conductive layer 14 has a refractive index of n1 and a thicknesses of t1, wherein n1≧N1>N2 and T2>t1>T1. The third and fourth undercoat layers 15, 16 have refractive indexes of N3 and N4, respectively, and have thicknesses of T3 and T4, respectively, and the second patterned transparent conductive layer 17 has a refractive index of n2 and a thicknesses of t2, wherein n2≧N3>N4 and T4>t2>T3. Therefore, the drawback of image deterioration caused by the patterning of the transparent conductive layers may be overcome and the optical difference between the patterned regions and the non-patterned regions may be reduced by adjusting the refractive indexes and thicknesses of the various thin layers that constitute the transparent conductive film.

In conclusion, the touch panel disclosed herein can surely achieve the intended objects and effects of the invention by virtue of the processing steps described above. While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. A touch panel comprising:
a plastic film substrate having a first surface and a second surface opposite to the first surface;
wherein the first surface is provided in sequence with a first undercoat layer, a second undercoat layer and a first patterned transparent conductive layer, and the first surface is further printed with a first patterned metal circuit layer along the periphery of the first patterned transparent conductive layer, and wherein the second surface is provided in sequence with a third undercoat layer, a fourth undercoat layer and a second patterned transparent conductive layer, and the second surface is further printed with a second patterned metal circuit layer along the periphery of the second patterned transparent conductive layer.

2. The touch panel according to claim 1, wherein the plastic film substrate has a thickness ranging from 2 μm to 300 μm, preferably from 2 μm to 200 μm.

3. A method for producing a touch panel, comprising the steps of:
Step A: providing a plastic film material;
Step B: cutting the plastic film material to obtain a sheet-like plastic film substrate having a first surface and a second surface opposite to the first surface and placing the plastic film substrate on a support frame for subsequent processing;
Step C: forming in sequence a first undercoat layer, a second undercoat layer and a first transparent conductive layer on the first surface of the plastic film substrate, and forming in sequence a third undercoat layer, a fourth undercoat layer and a second transparent conductive layer on the second surface of the plastic film substrate;
Step D: patterning the first and second transparent conductive layers into a first patterned transparent conductive layer and a second patterned transparent conductive layer, respectively;
Step E: forming a first patterned metal circuit layer and a second patterned metal circuit layer on the first and second surfaces of the plastic film substrate along the peripheries of the first and second patterned transparent conductive layers using a printing process, respectively; and
Step F: baking the resultant device to cure the first and second patterned metal circuit layers.

4. The method according to claim 3, wherein the Step D comprises the sub-steps of:
Step D-1: applying a temporary protective film the second transparent conductive layer;
Step D-2: supporting the plastic film substrate on a support member, with the second transparent conductive layer facing downwardly;
Step D-3: forming a first patterned etching-resistant layer over the first transparent conductive layer;
Step D-4: reversing the plastic film substrate with respective to the support member, with the first transparent conductive layer facing downwardly;
Step D-5: removing the temporary protective film applied over the second transparent conductive layer;
Step D-6: forming a second patterned etching-resistant layer over the second transparent conductive layer;
Step D-7: etching the first and second transparent conductive layers to remove the regions thereof unprotected by the first and second patterned etching-resistant layers; and
Step D-8: removing the first and second patterned etching-resistant layers.

5. The method according to claim 3, wherein the Step D comprises the sub-steps of:
Step D-10: applying a temporary protective film over the second transparent conductive layer;
Step D-20: supporting the plastic film substrate on a support member, with the second transparent conductive layer facing downwardly;
Step D-30: forming a first patterned etching-resistant layer over the first transparent conductive layer;
Step D-40: etching the first transparent conductive layer to remove the regions thereof unprotected by the first patterned etching-resistant layer, thereby forming a first patterned transparent conductive layer;
Step D-50: removing the first patterned etching-resistant layer and applying a temporary protective film over the first patterned transparent conductive layer;
Step D-60: reversing the plastic film substrate with respective to the support member, with the first patterned transparent conductive layer facing downwardly;
Step D-70: removing the temporary protective film applied over the second transparent conductive layer;
Step D-80: forming a second patterned etching-resistant layer over the second transparent conductive layer;
Step D-90: etching the second transparent conductive layer to remove the regions thereof unprotected by the second patterned etching-resistant layer, thereby forming a second patterned transparent conductive layer; and
Step D-100: removing the second patterned etching-resistant layer.

6. The method according to claim 3, further comprising a Step G intervening between the Step D and the Step E, wherein the Step G comprises annealing the first and second patterned transparent conductive layers, so as to have the first and second patterned transparent conductive layers crystallized.

7. The method according to claim 6, wherein the annealing Step G is performed at a temperature of 100˜200° C. for 30˜90 minutes.

8. The method according to claim 3, wherein the undercoat layers and transparent conductive layers are formed in the Step C by using a dry process selected from the group consisting of vacuum evaporation, sputtering and ion plating, or by using a wet process.

9. The method according to claim 3, wherein the first and second patterned metal circuit layers are formed in Step E by screen printing of conductive silver paste onto the plastic film substrate.

10. The method according to claim 3, wherein the baking Step F is performed at a temperature of 100˜200° C.
